(19) United States
(12) Patent Application Publication
(10) Pub. No.: US 2009/0242923 A1
(43) Pub. Date: Oct. 1, 2009

(54) Hermetically Sealed Device with Transparent Window and Method of Manufacturing Same

(75) Inventor: Joel Lee Goodrich, Westford, MA (US)

Correspondence Address: CHRISTOPHER P. MAIORANA, P.C., 24840 HARPER SUITE 100, ST. CLAIR SHORES, MI, 48080, US

(73) Assignee: M/A-Com, Inc., Lowell, MA (US)

(21) Appl. No.: 12/058,021

(22) Filed: Mar. 28, 2008

(51) Int. Cl. H01L 33/00

(52) U.S. Cl. 257/99; 438/26; 257/E33.058

(57) ABSTRACT

The invention is a hermetically sealed semiconductor die package wherein a surface of the die can be positioned very close to the hermetic package and a method of fabricating such a package. The invention is particularly suited to hermetically sealed circuit components, such as dies with a light emitting surface or light receiving surface for which it would be desirable to place the light emitting or light receiving surface as close as possible to a transparent window in the package so as to maximize the amount of light that can be transmitted out of the package.

### FIELD OF THE INVENTION

The invention pertains to hermetically sealed devices and the processes for manufacturing the same. The invention is particularly adapted for use in connection with light emitting or receiving devices because it permits the light-emitting or receiving surface of a device to be placed very close to a transparent window of the package.

### BACKGROUND OF THE INVENTION

Electrical components such as integrated circuit dies are used in a wide variety of applications in which it is necessary to hermetically seal the electric components from the environment in which they will be located. For example, integrated circuit dies used in environments with high humidity should be hermetically sealed from the high humidity environment in order to prevent corrosion of their electrical connections and/or other electronic components. Typically, electronic components are hermetically sealed in a ceramic or semiconductor enclosure.

In the case of electronic circuits that include light emitting surfaces, e.g., light emitting diodes (LEDs) that need to be hermetically sealed, the light emitting surface must be positioned adjacent a transparent window in the hermetic package in order to permit the light to be seen or received by another optical component, such as an optical fiber or optical receiver. Such a transparent window typically might be formed of glass (with or without an anti-reflection coating on either or both surfaces). The window would form part of the hermetic package.

FIG. 1 illustrates a typical hermetically sealed light emitting diode 102. The light emitting diode is embodied in a semiconductor die 100. In one common type of LED die, one of the major surfaces 100a of the die is the anode of the diode to which electrical contact must be made in order to provide current through the diode and the opposing surface 100b of the die 100 is the cathode (also to which electrical contact must be provided). One of these surfaces, typically the anode surface also is the surface from which light is emitted (the light emitting surface). The die is hermetically sealed in a package comprising a non-conductive (e.g., ceramic) base 104 and a glass lid 106. The glass lid 106 is formed to create a volume 108 within which the die 100 (and any other electrical components and connectors) can be encased between the base 104 and the lid 106. The base 104 and the cover 106 are sealed around the periphery of the die to each other by a suitable non-conductive sealing material such as a glass frit bead 110.

More particularly, the die 100 is mounted on the base via a suitable technique, such as soldering. The area of the base is larger than the area of the lid such that the base protrudes as shown by reference numeral 114 in FIG. 1A around the edge of the lid 106. A conductive metal 112 can be deposited on the base, such as by physical vapor deposition (PVD), and patterned, such as by conventional photolithography and chemical etching, to provide electrical leads from the die to external of the package. For instance, the cathode surface 100b may be electrically connected to a portion of the top surface of the base 104 outside of the hermetic seal via a first electrical lead 112a on the base 104. Electrical contact can be made to the anode via a wire bond 111 between the top surface 100a of the die to a second conductive lead 112b and then through that lead to outside of the hermetic seal. Hence, electrical contact can be made to the anode and cathode from external of the package.

Alternately, the base of the hermetic package can be fabricated so that it comprises portions of conductive material, such as silicon and portions of non-conductive material so that both the cathode and the anode can be electrically coupled to external components through the bottom of the base layer (while preventing the anode and the cathode from being electrically connected to each other). Merely by way of example, U.S. Pat. No. 7,026,223, incorporated herein fully by reference, discloses a hermetically sealed integrated circuit die structure in which contact to the top, anode side of the die to external of the package is made via wire bonds from the top, anode side of the die to the top surface of a conductive portion of the base and through the base to the bottom surface of the base via the conductivity of that portion of the base itself. The bottom, cathode side of the die is mounted to a different, electrically separated conductive portion of the base via a conductive mounting material, such as solder, so that the cathode can be electrically connected to external circuitry through the base.

While both of these techniques for providing electrical contact between the terminals of the diode and external circuitry are advantageous in their own respects, they both require wire bonds from the top, anode surface of the die to the surface of the base.

In order to maximize the amount of light from a light-emitting surface that is transmitted through the transparent window, it is desirable to place the light-emitting surface of the die as close as possible to that window. However, the use of wire bonds to connect the top, anode surface of the die to the surface of the base, wherein the top, anode surface of the die also is the light emitting surface, limits how close the transparent window can be placed to the light emitting surface. Particularly, a typical wire used in wire bonding might be on the order of about 25 microns in diameter. Further, a well-made wire bond that will not break under normal conditions forms a loop from the surface of the die, at one end of the wire bond, to the surface of the substrate, at the other end of the wire bond. This loop of wire must have a certain shape and, therefore, a certain maximum height above the top surface of the die in order to form a suitable loop that will withstand breakage. Typically, the wire loop of a wire bond may have a maximum height of approximately 100 microns above the top surface of the die (e.g., the light emitting surface) at its highest point. This circumstance, in turn, requires that the window be positioned at a distance from the light-emitting surface of the die greater than the maximum height of the wire bond loop above that surface.

### SUMMARY OF THE INVENTION

The invention is a hermetically sealed semiconductor die package wherein a surface of the die can be positioned very close to the hermetic package and a method of fabricating such a package. The invention is particularly suited to hermetically sealed circuit components, such as dies with a light emitting surface or light receiving surface for which it would be desirable to place the light emitting or light receiving surface as close as possible to a transparent window in the package so as to maximize the amount of light that can be transmitted out of or into the package.

In accordance with a first aspect of the invention, a method of fabricating a hermetically sealed die is provided comprising depositing a conductive layer on a base substrate, mounting a die having first and second opposing surfaces to the conductive layer with the first surface thereof in electrical contact with the first conductive layer, hermetically sealing a conductive frame to the conductive layer, the conductive frame surrounding the die, and hermetically sealing a lid on top of the frame and the die, the lid comprising at least a first conductive portion in electrical contact with a second surface of the die opposite the first surface and a second conductive portion electrically isolated from the first conductive portion in electrical contact with the frame.

In accordance with a second aspect of the invention, a hermetically sealed die is provided comprising a base substrate, a conductive layer on the base substrate, a die mounted to the conductive layer so as to provide conductive contact between a first surface of the die and a portion of the first conductive layer, a conductive frame hermetically sealed to the substrate surrounding the die in contact with at least a portion of the first conductive layer, and a lid hermetically sealed on top of the frame and the die, the lid comprising at least a first conductive portion in electrical contact with a second surface of the die opposite the first surface and a second conductive portion electrically isolated from the first conductive portion in electrical contact with the frame.

### DESCRIPTION OF THE DRAWINGS

FIG. 1 is a cross-sectional elevation view of a hermetically sealed LED die in accordance with the prior art.

FIG. 2 is a cross-sectional elevation view of a hermetically sealed LED die in accordance with the principles of the present invention.

FIGS. 3A-3H are cross-sectional elevation views of portions of the hermetically sealed LED die of FIG. 2 shown at various stages of fabrication.

### DETAILED DESCRIPTION

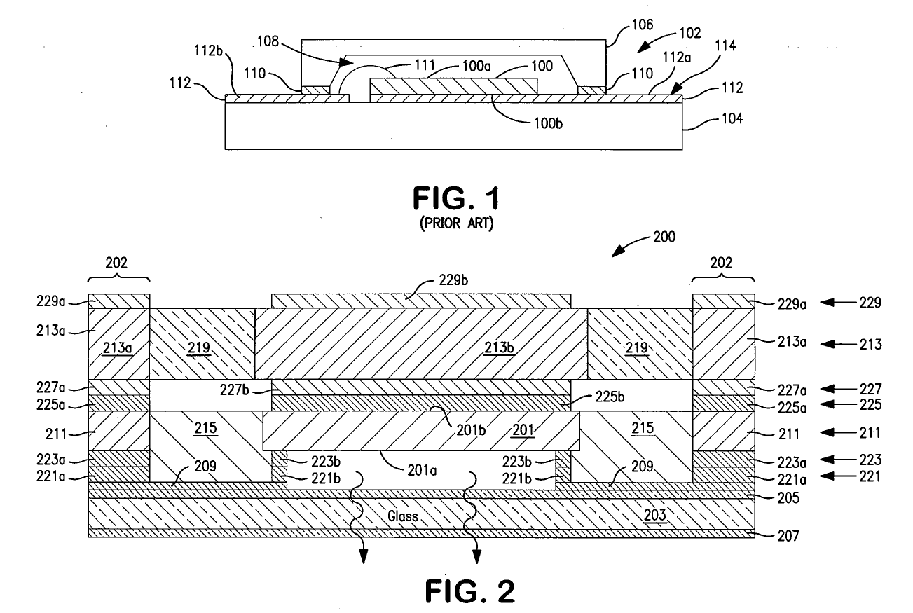

FIG. 2 illustrates a hermetically sealed LED die package 200 in accordance with the principles of the present invention. In accordance therewith, an LED die 201 is hermetically sealed between a glass base layer 203 through which light from the light emitting surface 201 a of the die can pass and a lid 213. The lid 213 is comprised of conductive portions, such as silicon portions 213a and 213b and non-conductive portions, such as glass portion 219. The glass substrate 203 and the lid 213 are hermetically sealed to each other via a wall 202 completely surrounding the die formed of plurality of layers of materials including conductive metal layer 209, first pair of mating solder layers 221 and 223, silicon layer 211, and second pair of mating solder layers 225 and 227. Note that the die in FIG. 2 is upside down compared to the die in FIG. 1. That is, the light-emitting surface of the die 201a in FIG. 2 is the bottom surface, whereas the light-emitting surface of the die in FIG. 1 is the top surface.

It also should be noted that terms such as bottom and top or vertical and horizontal are used herein only in their relative senses to each other in order to simplify the description and are not intended to require or insinuate any particular orientation of the device package. It also needs to be understood that the drawings are not drawn to scale. Particularly, some of the layers are significantly exaggerated in thickness relative to the other layers, such as all of the solder layers, in order to clearly show them.

Although the anode and cathode contacts of the die are on opposite surfaces of the die 201, all electrical contacts on the exterior of the package 200 are on same side of the package, and, particularly, on the exterior of the lid 213. Particularly, the cathode 201b of the die 201 is electrically coupled to a metal contact 229b formed on the external surface of the lid 213 through portion 225b of solder metal layer 225, corresponding portion 227b of solder metal layer 227, and portion 213b of the silicon lid 213.

With respect to the anode on surface 201a of the die 201, electrical contact is made between the anode on side 201a of the die and metal contact 229a formed on the external surface of the lid 213 through portion 223b of solder metal layer 223, corresponding portion 221b of solder metal layer 221, conductive path 209, portion 221a of solder metal layer 221, corresponding portion 223a of solder metal layer 223, silicon layer 211, portion 225a of solder metal layer 225, a corresponding portion 227a of solder metal layer 227, and portion 213a of the silicon lid 213.

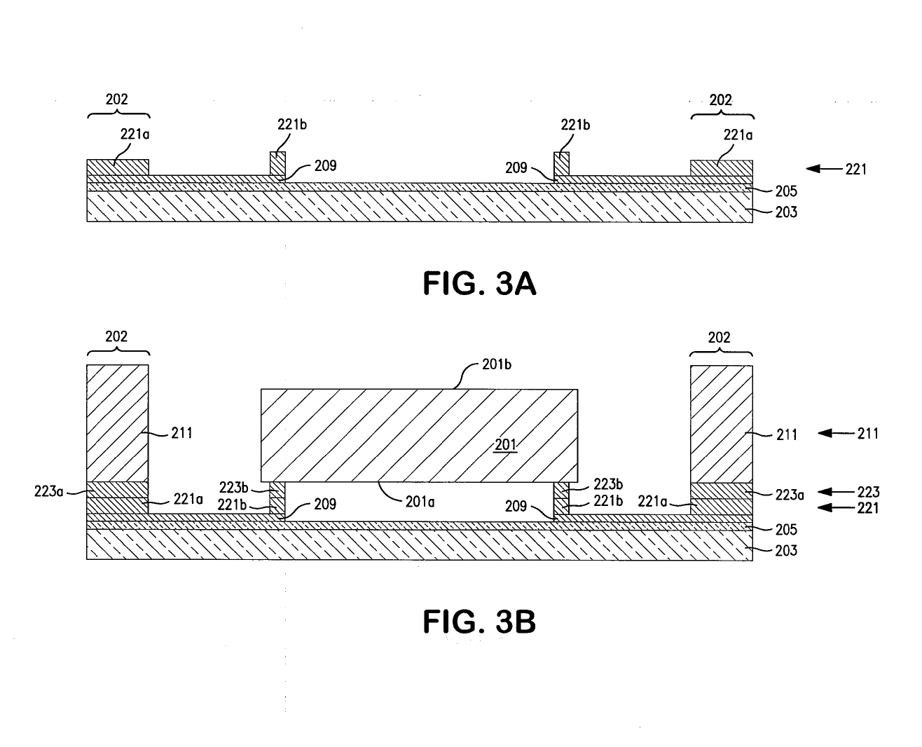

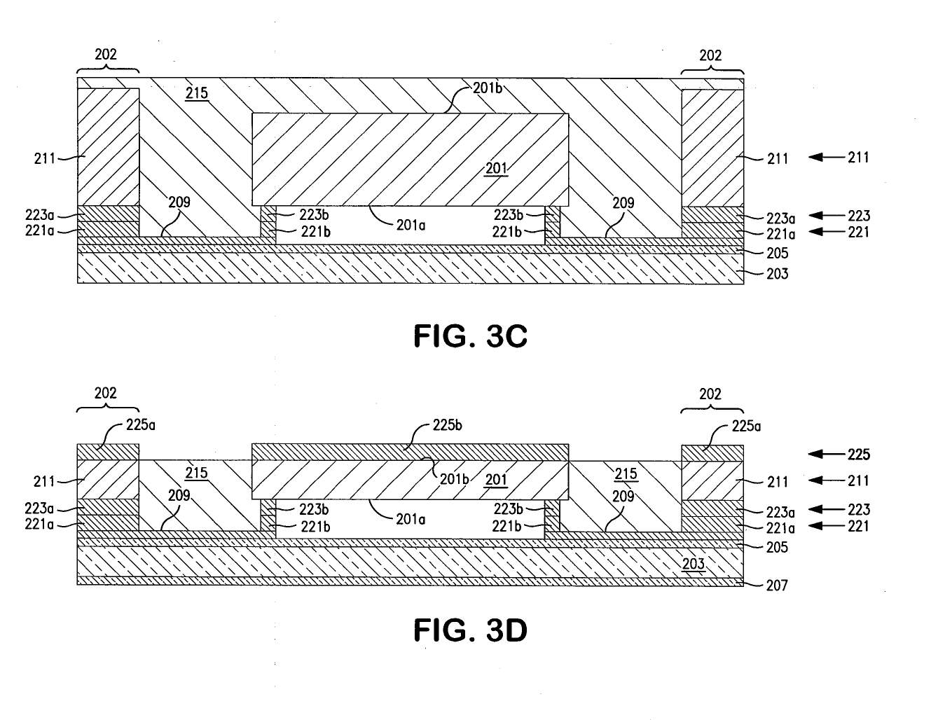

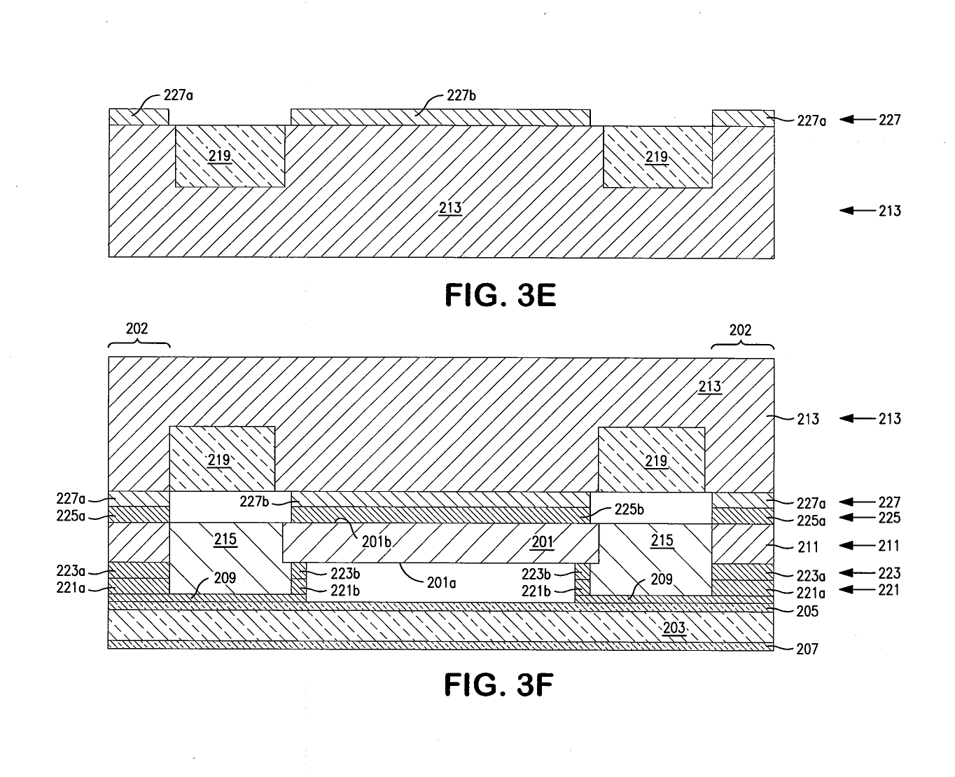

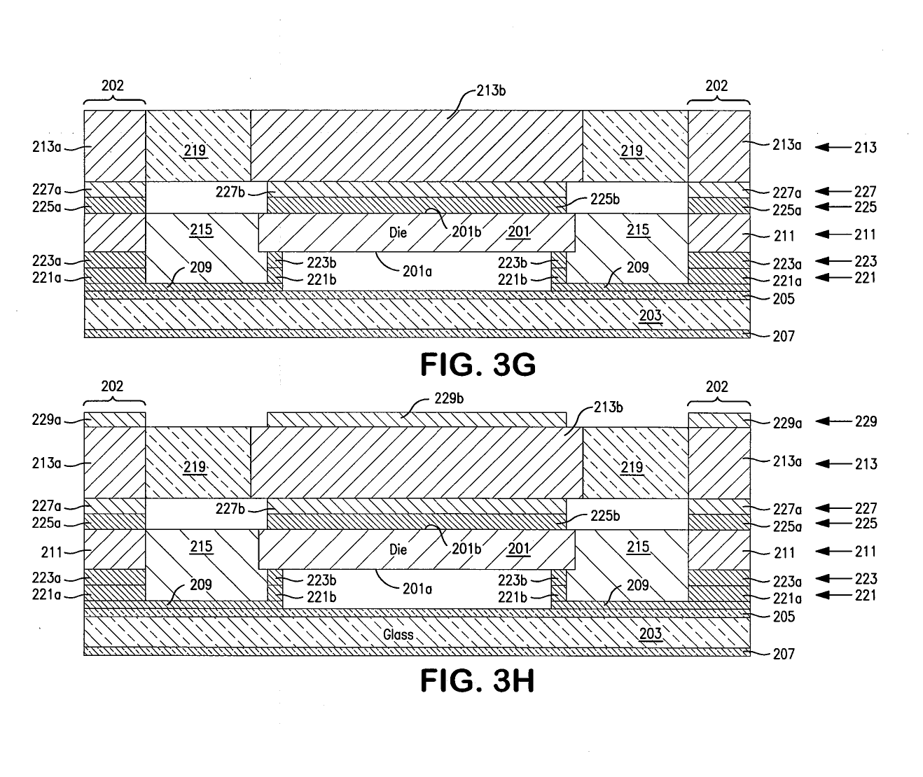

Note that FIGS. 2 and 3A-3H are cross sectional elevation views, which inherently show only a single slice through the device. However, although not perceivable in these Figures, as noted above, the hermetic sealing wall 202 completely surrounds the die 201. Thus, for instance, solder joint 225a completely surrounds die 201, and thus intersects the planar slice seen in FIG. 2 twice, namely once on the left side of the die and once on the right side of the die, as shown. Thus, the two portions of solder layer 225 labeled 225a in FIG. 2 are, in fact, the same solder joint, and merely represent the two different points at which a single continuous solder bead around the die intersects the plane of FIG. 2. On the other hand, solder joint 225b formed in layer 225 is electrically separate from solder joint 225a.

One of the advantages of this design is that it has no wire bonds to make electrical contact to the anode on the light emitting surface 201a of the die 201. Hence, the light-emitting surface 201 can be placed very close to the window layer 205. In the illustrated embodiments, the distance between the glass substrate 203 and the light-emitting surface 201a of the die 201 is merely the combined depths of the metal conductor layer 209 and the two solder layers 221 and 223. In fact, as will be discussed in more detail further below, in certain embodiments, the solder layers 221 and 223 may be eliminated.

As noted above, the depths of the solder layers 221, 223 as well as the conductive trace layer 209 are not drawn to scale, but are exaggerated in order to show them more clearly. The thickness of these three layers combined can be less than 10 microns. In addition, while FIG. 2 illustrates an embodiment in which the die 201 is attached to the conductive trace layer 209 on glass 203 via solder joints, the die alternately can be attached directly to the conductive trace layer 209 without the need for solder joints by thermo-compression bonding, thereby moving the light emitting surface 201 a even closer to the glass substrate 203. In such an embodiment, the distance between the light-emitting surface of the die and the glass substrate would be only the thickness of the conductive metal layer.

While FIG. 2 as well as the subsequent FIGS. 3A-3G illustrate a single die, this is merely for purposes of clarity in order not to obfuscate the invention. It will become clear from the following discussion that the fabrication process discussed herein can be performed at the wafer level and then the wafer simply diced into individual hermetically sealed dies.

FIGS. 3A-3H are cross-sectional elevation views of the hermetically sealed LED circuit 200 of FIG. 2 shown during various stages of the fabrication process and help illustrate the fabrication process as will be described herein below.

It should be noted that, while the various steps of the process are described in a particular order herein below, the described order of the steps is merely exemplary and that many of the steps could be performed at different times.

With reference FIG. 3A, the process starts with a glass substrate 203. Preferably, the glass substrate will be coated with an anti-reflection coating on one or both faces thereof. As a manufacturing practicality, the top surface the glass substrate 203 is coated with anti-reflection coating 207 near the beginning of the process, whereas the external surface of the glass 203 can be coated at virtually any stage of the process because the external surface is always entirely exposed and available for processing.

In any event, a first layer of metal is deposited and patterned to form conductive leads 209 on the internal surface of the glass substrate. This layer of metal can be deposited and patterned using any conventional metal deposition technique, such as physical vapor deposition (PVD) and then patterned using any conventional patterning technique, such as photolithographic patterning followed by chemical etch, to put down the conductive leads as needed for the particular circuit design. This would, of course, include at least, the aforementioned metal patterns to connect the anode surface 201a of the die 201 to the wall 202 of the hermetic package.

If the die 201 and/or the silicon portion 211 of the peripheral wall 202 will be attached to the conductive leads 209 by solder bonding, then a layer of solder metal 221 is deposited and patterned. The pattern would be to provide at least a first solder joint 221b where the die 201 will be attached to the conductive lead 209 and a second solder joint 221a where the peripheral wall 202 will be attached to the conductive lead 209. For instance, the solder metal layer 221 would be patterned to form two square solder beads (or joints) 221a and 221b as shown in the cross-sectional view of FIG. 3A. As previously noted, FIG. 3A is a cross-sectional view and thus, in this view, we see the two points labeled 221a where beads 221a intersects the cross sectional plane of the figure. Solder joint 221b will form a connection from the anode surface 201 a of the die to the conducive lead 209 and solder joint 221a will form a connection from the other end of the lead 209 to the wall 202.

Next, with reference to FIG. 3B, the die 201 is brought to the glass substrate 203 for attachment thereto. The die 201 has had a solder joint 223b corresponding in shape and size to solder joint 221b on shape and size formed around the periphery of the light emitting surface 201a. The die 201 is mounted with the light emitting surface 201a facing downwardly toward the glass and with the solder joints 221b, 223b mating. The two are soldered together conventionally.

As previously noted, if thermo-compression bonding is employed rather than soldering, then both solder layers 221 and 223 can be eliminated and the anode surface 201a of the die 201 can be thermo-compression bonded directly to the first metal layer 209 without the solder layers.

Also as seen in FIG. 3B, the semiconductor portion 211 of the wall 202 also is placed on the glass substrate. Assuming that solder bonding is employed to attach the silicon 211 to the lead 209, then another solder joint 223a is formed on the silicon wall that matches the corresponding solder joint 221a on the glass 203 and metal 209.

The silicon portion 211 of the wall 202 may be formed by etching a wafer of silicon completely through in the middle so as to leave only an enclosed frame (or peripheral wall) of silicon surrounding open-space. Then, that wall is soldered to the glass substrate 203 and lead 209 as shown in FIG. 3B.

Again, if, instead of using solder bonding, thermo-compression bonding is used to attach the silicon frame to the glass substrate, then both solder joints 221a and 223a could be eliminated and the silicon portion of the wall 202 could be directly thermo-compression bonded to the metal lead 209.

Turning to FIG. 3C, in the next step of the fabrication process, an epoxy 215 is placed over the entire wafer, such as by spin coating, to fill in the lateral spaces between the die and the wall 202.

Then, with reference to FIG. 3D, the epoxy 215, silicon 211, and cathode surface 201b of the die 201 are polished down to provide a planar surface at which the top of the silicon portion 211 of the wall 202 and the cathode surface 201 a of the die 201 are exposed and wherein the spaces there between are filled with epoxy 215.

Still referring to FIG. 3D, next, solder 225 is deposited over the planar surface at the top of the structure and patterned to provide at least (1) a solder joint 225a on top of the silicon portion 211 of the peripheral wall 202 for making external electrical contact to the anode and (2) a solder joint 225b on the cathode surface 201b of the die 201 for purposes of making external electrical contact with the cathode.

Turning now to FIG. 3E, next, a silicon substrate 213 that will become the lid of the package is provided. Silicon substrate 213 has been selectively etched to provide openings that correspond generally in position and size in the lateral dimension to the spacing between the die 201 and the wall 202, i.e., the spaces in the package that are filled with epoxy 215. These spaces have been filled with a non-conductive material, such as glass 219. The glass can be deposited in the etched volumes using any reasonable technique heretofore known or later discovered. Merely as an example, the etched silicon substrate may be spin coated with glass and then polished down to or slightly beyond the top surface of the silicon.

Next, solder metal 227 may be deposited on top of the silicon and patterned into solder joints 227a and 227b to mate with the solder joints 225a and 225b, respectively that were formed on the top surface of the structure depicted in FIG. 3D as previously described. Again, the solder metal can be deposited and patterned using any reasonable technique presently known or later discovered.

Next, with reference to FIG. 3F, the silicon substrate 213 with the glass 219 filling the voids and the solder joints 227a and 227b thereon is flipped over and soldered on top of the structure previously fabricated as described in connection with steps 3A-3D. Alternately, the lid can be attached via thermo-compression bonding using suitable metals.

lf an external anti-reflection coating 207 on the external side of the glass 203 is desired and has not already been deposited, it can be deposited at this time.

Next, referring to FIG. 3G, the top surface of the silicon lid 213 is polished down to at least the tops of the glass portions 219 within the silicon substrate. This polishing to expose the tops of the glass portions electrically isolates the cathode contact stack (comprising portions 225b, 227b, and 213b) from the anode contact stack (comprising 221a, 223a, 211, 225a, 227a, and 213a).

Finally, referring to FIG. 3G, which is essentially identical to the finished product as depicted in FIG. 2, contact metal is deposited and patterned on the top of the lid 213 to form an anode contact 229a and a cathode contact 229b. This is the final product.

As just noted, contact external of the package is made to the cathode of the die via contact metallization 229b, lid portion 213b, and solder joints 227b and 225b. External contact to the anode surface 201 a of the die 201 is made via contact metallization 229a, lid portion 213a, solder joints 227a and 225a, silicon wall portion 211, solder joints 223a and 221a, metal lead 209 and solder joints 221b and 223b.

Assuming the fabrication process is performed at the wafer level, the wafer can then be diced into the individual hermetically sealed dies. Particularly, in a preferred embodiment of the invention, the wafer is diced directly through the middles of the sealing silicon peripheral walls 202.

Hence, the die is hermetically sealed in a package in which the peripheral walls 202 of the package are conductive in order to provide connection from the anode side 201 a of the die 201 to the top side of the hermetically sealed package such that both the cathode and the anode contacts are on the same side of the hermetically sealed package. Furthermore, the light-emitting surface of the die is positioned extremely close to the glass since no wire bonds are used. The light emitting surface 201a of the die is spaced from the internal surface of the glass substrate 203 by merely the thickness of the metal layer or layers 209, 221 and/or 223 formed on the glass substrate for electrical contact purposes and for purposes of mounting the die on the glass substrate 203.

Having thus described a few particular embodiments of the invention, various alterations, modifications, and improvements will readily occur to those skilled in the art. For instance, the invention has been described in connection with a die having a light-emitting surface, such as an LED. However, similar considerations may be applicable to other light emitting components whether embodied on an integrated circuit die or otherwise. In addition, the invention can be equally attractive for application in connection with dies or other circuitry having light receiving components. Furthermore, the invention is not exclusively beneficial in connection with circuitry having light emitting or receiving surfaces. There may be many other reasons that a circuit designer may wish to bring the surface of a die or other circuitry as close as possible to the surface of a hermetic package and the invention may be applied in such application regardless of whether the circuit has a light emitting or receiving surface and/or a transparent window. Such alterations, modifications, and improvements as are made obvious by this disclosure are intended to be part of this description though not expressly stated herein, and are intended to be within the spirit and scope of the invention. Accordingly, the foregoing description is by way of example only, and not limiting. The invention is limited only as defined in the following claims and equivalents thereto.

1. A hermetically sealed die comprising:
a base substrate;
conductive layer on the base substrate;
a die mounted to the conductive layer so as to provide conductive contact between a first surface of the die and a portion of the first conductive layer;
a conductive frame hermetically sealed to the substrate surrounding the die in contact with at least a portion of the first conductive layer; and
a lid hermetically sealed on top of the frame and the die, the lid comprising at least a first conductive portion in electrical contact with a second surface of the die opposite the first surface and a second conductive portion electrically isolated from the first conductive portion in electrical contact with the frame.

2. The hermetically sealed die of claim 1 wherein the frame is formed of semiconductor.

3. The hermetically sealed die of claim 2 wherein the frame is formed of a semiconductor substrate that has been etched through in its middle.

4. The hermetically sealed die of claim 1 wherein the base is transparent and the first surface of the die is light emitting.

5. The hermetically sealed die of claim 1 wherein the base is glass.

6. The hermetically sealed die of claim 1 wherein the base is glass and is coated with an anti-reflection coating.

7. The hermetically sealed die of claim 1 wherein at least one of the hermetic seal between the conductive layer and the frame and the hermetic seal between the frame and the lid comprises a thermo-compression bond.

8. The hermetically sealed die of claim 1 wherein at least one of the hermetic seal between the conductive layer and the frame and the hermetic seal between the frame and the lid comprises a solder joint.

9. The hermetically sealed die of claim 8 further comprising:
a first solder bead on the conductive layer surrounding the die; and
a second solder bead on the frame;
wherein the hermetic seal between the conductive layer and the frame is provided by the first solder bead and the second solder bead being soldered to each other.

10. The hermetically sealed die of claim 1 wherein the lid comprises portions of semiconductor separated by portions of insulator.

11. The hermetically sealed die of claim 10 wherein the insulator comprises glass.

12. The hermetically sealed die of claim 1 further comprising:
epoxy in a volume between the die and the frame.

13. The hermetically sealed die of claim 1 wherein the die is a light emitting diode and wherein the first surface of the die is a light emitting surface and an anode and the second surface of the die is a cathode.

14. A method of fabricating a hermetically sealed die comprising:
depositing a conductive layer on a base substrate;
mounting a die having first and second opposing surfaces to the conductive layer with the first surface thereof in electrical contact with the first conductive layer;
hermetically sealing a conductive frame to the conductive layer, the conductive frame surrounding the die;
hermetically sealing a lid on top of the frame and the die, the lid comprising at least a first conductive portion in electrical contact with a second surface of the die opposite the first surface and a second conductive portion electrically isolated from the first conductive portion in electrical contact with the frame.

15. The method of claim 14 wherein the hermetically sealing of at least one of the conductive frame to the conductive layer and the lid to the frame and the die comprises thermo-compression bonding.

16. The method of claim 14 wherein the hermetically sealing of at least one of the conductive frame to the conductive layer and the lid to the frame and the die comprises soldering.

17. The method of claim 14 further comprising:
filling a volume between the die and the frame with a material;
polishing the material, the second surface of the die, and the frame to create a planar surface.

18. The method of claim 14 further comprising:
fabricating the lid by;
etching a first surface of a semiconductor substrate to create voids partially through the semiconductor;
filling the voids with an insulator; and
polishing a second surface of the semiconductor substrate opposite the first surface down to expose the insulator at the second surface.

19. The method of claim 14 wherein the substrate is glass and the first surface of the die is a light-emitting surface.

20. The method of claim 19 further comprising:
coating the glass with anti-reflection coating.
